(19) United States
(12) Patent Application Publication
(10) Pub. No.: US 2013/0275065 A1
(43) Pub. Date: Oct. 17, 2013

(54) METHOD FOR PREDICTING THE POWER AN ELECTROCHEMICAL ENERGY STORE CAN OUTPUT TO AN ELECTRICAL LOAD

(71) Applicants: Roland Rathmann, Vierkirchen (DE); Claus-Rupert Hohenthanner, Hanau (DE); Tim Schaefer, Harztor (DE); Joerg Kaiser, Eggenstein (DE)

(72) Inventors: Roland Rathmann, Vierkirchen (DE); Claus-Rupert Hohenthanner, Hanau (DE); Tim Schaefer, Harztor (DE); Joerg Kaiser, Eggenstein (DE)

(73) Assignee: Li-Tec Battery GmbH, Kamenz (DE)

(21) Appl. No.: 13/818,487

(22) PCT Filed: Aug. 1, 2011
(86) PCT No.: PCT/EP11/03854

§ 371 Date: Jul. 5, 2013

(30) Foreign Application Priority Data
Aug. 25, 2010 (DE) 10 2010 035 363.9

(51) Int. Cl. G01R 31/36

(52) U.S. Cl. CPC G01R 31/362
USPC 702/61

(57) ABSTRACT

In a method for predicting the electrical power an electrochemical energy store can output to a consumer, a processor device preferably processes at least one measurement from a plurality of measurements of the cell voltage depending on time in an information technological manner, said measurements being carried out previously on an electrochemical energy store of the same design which is subject to a plurality of discharges of the electrochemical energy store and has a power output that is constant over time and the measurements being stored in a digital memory device.

The present invention relates to a method for predicting the electrical power an electrochemical energy store can output to an electrical load.

In some applications of electrochemical energy stores, in particular for electric vehicles, the amount of power an electrochemical energy store can output over a specific amount of time plays an important role. For example, before initiating the overtaking of another vehicle, the driver of an electric vehicle needs to be able to rely on the respective state of the vehicle's traction battery being capable of supplying the power needed and it being able to output it to the drive unit to accelerate the vehicle when needed so as to safely pass the other vehicle.

DE 10 107 583 A1 discloses a method for determining the power response of a storage battery by evaluating the voltage drop occurring upon a high current load over time. A voltage value is thereby selected from the voltage response of the storage battery after a high current load has been switched on and a status value is then determined from the voltage value as well as the battery temperature and state of charge by functional association. Said status value is compared to a preset value which at the least is a function of the associated battery temperature and the associated state of charge of the storage battery.

DE 102 03 810 A1 discloses a method for determining the state of charge and/or the power response of a charge storage device based on estimations factoring in estimations and information obtained from at least two different operating points or operating conditions of the energy store. These estimations are effected with regard to a current and/or future charge state and/or a current and/or future power response of the charge store.

DE 10 2005 050 563 A1 discloses a method for predicting the power response of an electrical energy store. In this method and the associated apparatus for predicting the power response of an electrochemical energy store, a mathematical model for the energy store is used to continuously adapt its status variables and parameters, and thus estimate and predict charge/discharge power capacity.

The present invention is based on the object of specifying a technical teaching for predicting the power able to be output by an electrochemical energy store to an electrical load which is capable of overcoming the disadvantages or limitations of known methods to the greatest extent possible.

The object is accomplished by a method of predicting the power able to be output by an electrochemical energy store to an electrical load in accordance with claim 1.

The invention thereby provides for a method of predicting the power able to be output by an electrochemical energy store, particularly to an electrical load, in which a processing device preferably processes at least one measurement from a plurality of measurements previously made of an electrochemical energy store of the same design subject to a plurality of discharges over time at a constant power output and electronically processes cell voltage measurements preferably stored in a digital memory device as a function of time. Thus, a processing device preferably electronically processes one or more measurements, wherein said measurement(s) originate from a plurality of discharges of the electrochemical energy store at a constant power output over time previously obtained and stored from an electrochemical energy store of the same design and wherein said measurements relate to the cell voltage as a function of time.

In conjunction with the description of the present invention, a prediction of the power an electrochemical energy store can output to an electrical load is thereby to be understood as generating information related to the potentiality of the electrochemical energy store to output power over a specific time period temporally following the specific time of the prediction.

The prediction is thereby preferably provided as a response to a query made by an information-processing system which is preferably a component of a control device of the electrical load to which the power is to be output. The query thereby preferably contains a predefined output power and a designated time interval over which the predefined power is to be output.

In conjunction hereto, an electrochemical energy store refers to a device which can store energy in chemical form and output it in electrical form. It is thereby preferably a galvanic cell or a networked plurality of galvanic cells connected in parallel and/or in series or e.g. a fuel cell. Particularly preferential examples of electrochemical energy stores are so-called secondary cells which not only can output energy but which can also receive energy in electrical form and store it in chemical form. Lithium ion cells are notable examples of such secondary cells.

In conjunction hereto, the power able to be output to an electrical load refers to the flow of energy; i.e. the energy per unit of time, the electrochemical energy store is capable of outputting to the electrical load. The electrical load is thereby preferably an electric motor or preferably comprises such an electric motor which delivers the power emitted to it to a mechanical system, preferably the chassis of a vehicle, and supplies it to said system.

A processing device in the present context is to be understood as any device which is capable of electronically processing data. This term is thus not limited to processors in the narrower sense but rather particularly includes any type of electronic circuit, particularly any logic circuit, integrated circuit memory and/or combination of such circuits such as for example an address decoder, a semiconductor memory or other similar circuits, by means of which electronic processing of at least one measurement is possible.

Preferred embodiments of the invention provide for the power output to be predicted as a response to a query from an IT-supported system. If the query is made for example in the form of indicating a required power and time interval during which the power is needed, the processing device can then for example be a logic circuit which can generate a storage address or a plurality of storage addresses from the query, by means of which the prediction of the power able to be output or other variables from which the prediction of the power to be output can be made can be retrieved from a digital memory device. Other embodiments of the invention provide for interpolation, in which for implementing same, the processing device preferably comprises a processor in the narrower sense, particularly one suited to numerical calculations, the technical devices of which can advantageously realize the interpolation. The specific design of the processing device to implement the inventive method depends on the respective embodiment of the inventive method utilized.

To be understood by electronic processing in the present context is any processing of data suited to generating a prediction of the power able to be output using a processing device in the stated sense. Electronic processing in terms of the present invention can thereby comprise numerical calculating operations; although this may not necessarily be the case. In some embodiments of the invention, the IT-supported processing can also be limited to simple logic operations.

An electrochemical energy store of the same design refers in the context of the description of the present invention to an electrochemical energy store, its relevant physical properties substantially equal to the electrochemical energy store for which the power it can output is to be predicted. In accordance with the invention, the measurements are made of an electrochemical energy store of the same design and these measurements are used to generate a prediction of the power an electrochemical energy store can output.

The electrochemical energy store used to carry out the measurements can preferably also be identical to the electrochemical energy store for which performance is to be predicted. One accordingly preferred embodiment of the invention provides for the measurement values to be collected during specific operating phases in which the electrochemical energy store is not in productive use and in which it can thus perform such measurements at a constant power output. Other preferred embodiments of the invention provide for the measurements to be performed during productive operating phases in which the power output can be kept or remains substantially constant.

To this end, the cell voltage profile is preferably measured as a function of time for a plurality of discharge operations for the electrochemical energy store used for the measurement. The power output during the measuring period is kept constant in these measurements. Doing so thus returns a host of measurement curves, whereby each of said curves corresponds to a constant power output at a specific value, and whereby each of said curves represents the cell voltage performance as a function of time during a discharge operation at the respective output power.

These measurements are first made on the electrochemical energy store of the same design and preferably stored in a digital memory device.

In one preferred embodiment of the invention, the cell voltage measurements are parameterized as a function of time pursuant the electrochemical energy store's operating temperatures. This means that cell voltage is measured separately as a function of time for a series of different electrochemical energy store operating temperatures and that a set of measurement data is stored for each of these temperatures. It is in this way possible to adequately take into account the electrochemical energy store's different physical behavior at different temperatures when predicting the available power.

In the later prediction of specific power, the query will then not only preferably contain the power to be output and preferably also the time interval during which the power is to be output, but rather also the electrochemical energy store's current operating temperature at which the power is to be output. In this case, the processing device which electronically processes the query in order to generate a corresponding prediction evaluates the stored measurement data relative the electrochemical energy store's current operating temperature within the query. By so doing, the prediction corresponds to the electrochemical energy store's actual operating temperature prevailing at the time the prediction was generated.

As already noted above, in various embodiments of the invention, the prediction of the power which can be output by the electrochemical energy store is a response to an IT-supported querying of an electrical load or a control device of the electrical load to a processing device of the electrochemical energy store which refers to a power to be output and a time interval over which the power is to be output to the electrical load by the electrochemical energy store. In some embodiments, the query can include even further information such as e.g. the operating temperature or other physical variables or influencing factors which can impact the specific power available. The electrical load or its control device preferably avail themselves of common communication technologies, as for example the use of a data bus or other such similar common devices, to generate and transmit the query to the processing device to respond to said query.

A further preferred embodiment of the invention provides for a method in which if the power to be output is not consistent with one of the performance values for which measurements were taken, the prediction is obtained by interpolating between performance value measurements proximate the power to be output. In this embodiment of the invention, a prediction of the power able to be output for which no measurement curves are stored in the digital memory device because no measurements were made of these performance value(s) is thus estimated, i.e. preferably sampled. In order to nevertheless enable a prediction to be made of the power able to be output with the inventive method, the invention provides in these embodiments for determining the power which can be output by interpolation, same relying on the measurement data collected for the performance values which are proximate to the performance value required for the prediction.

A first such embodiment of the invention provides for determining an interpolated measurement curve or a plurality of interpolated measurement curves, for example for different parameters such as e.g. the temperature of the electrochemical energy store, by interpolating measurement curves for proximate performance values and subsequently proceeding in similar manner with the measurement curves thus determined by interpolation as if the measurement curve determined by interpolation were based on an actual series of measurements. The interpolation of measurement curves is thereby preferably determined by an arithmetical averaging of the measured values of the measurement curves to proximate performance values. Said arithmetical averaging preferably weighs the measurement values to be averaged with the weighting factors on which the interpolation is based corresponding to the difference; i.e. the distance between the power on which the prediction is to be based and the performance values employed for the measurements.

A second embodiment for the interpolation provides for the predictive values, i.e. the probabilities at which a required power can be output, to be determined by interpolating the predictive values of proximate performance values. A further embodiment provides for the time interval of the prediction to be determined by interpolating from the time intervals over which a proximate performance value to the performance value to be queried can be output to the electrical load. The expert can draw on his general expertise to easily come up with further numerical and non-numerical methods of interpolation, such as e.g. so-called fuzzy methods.

A further embodiment of the invention provides for the response to a query of whether a power P to be output over a time interval Δt can be output to the electrical load to be given as an indication of probability. This probability indication can preferably be a quantitative indication of probability in the form of a real number between 0 and 1. Other preferred embodiments of the invention provide for an indication of probability in the form of a qualitative indication, preferably in the form of selecting a form response from a plurality of possible form responses, each one representing the probability of a reliability or a certainty at which the power P to be output over the time interval Δt can be output to the electrical load.

To predict the power to be output, one embodiment of the inventive method thereby preferably performs the following steps:
a) Determining a first measuring point MP1 on a measuring curve MK(P) for the power P to be output, its cell voltage U1 being as close as possible to the current cell voltage of the electrochemical energy store;
b) Determining the cell voltage U2 associated with the power P to be output at the second measuring point MP2 on measuring curve MK(P), its time coordinate t2=t1+Δt being offset from the time coordinate t1 of the first measuring point MP1 by time interval Δt; and
c) Determining the response as a function of the cell voltage U2.

The response is all the more moderate the lower the distance is between the cell voltage U2 at the end of discharging relative to the minimum cell voltage Umin which is not to be undershot without causing permanent damage to the electrochemical energy store. If U2 is below Umin, the response is then deprecative or at least accompanied by a warning that the requisite power may at best only be available in an emergency. As long as U2 is above Umin, the response is preferably all the more moderate the lower the distance is between the cell voltage U2 at the end of discharging relative to the minimum cell voltage Umin.

The response is also all the more moderate the closer the time tmax, at which the cell voltage is equal to Umin, is to time t2. If tmax is less than t2, the response is then deprecative or at least accompanied by a warning that the requisite power may at best only be available in an emergency.

A response or prediction is thereby all the more moderate the lower the indicated probability, reliability or certainty for the response or prediction at which the requisite power can be provided, thus output to the electrical load, or the shorter the relevant time interval is for the power output returned with the response or prediction to the requesting IT system.

In accordance with a further preferred embodiment, the cell voltage U2 determined prior to generating or calculating the response is further corrected by a value ΔU which factors in a potential or actual change in the internal resistance of the electrochemical energy store as of the time it was placed into operation, particularly due to the aging of the electrochemical energy store. The correction value ΔU is thereby preferably taken from a table of correction values which is preferably stored in a digital storage medium and which contains the correction values measured on similar electrochemical energy stores as a function of their aging, i.e. particularly as a function of their previous history with respect to these electrochemical energy stores being charged due to power consumption. To calculate a correction value ΔU, a numerical stored battery model is preferably also used, for example in form of parameterized curves, which enables calculating the correction values based on measurable battery parameters.

The power to thereby be output is preferably understood as the additional output of the battery as a whole, which can consist of a plurality of cells, to the currently required basic load. The load of each individual cell is thereby preferably calculated. It is hereby possible to take limitations of the entire battery's capacity into account, following for example from a high temperature dependency of the internal resistances at different cells, wherein the cells can exhibit different temperatures such that individual cells fall short of the minimum cell voltage before other cells.

A criterion is thereby preferably used with which the product of the power to be output and the time interval over which the power is to be output have to be less than or equal to the time integral of the product of cell voltage and cell current. This condition can be used for numerical prediction when the temporal performance of the cell voltages and the currents flowing during power output are known. Such data can preferably be collected in advance by measuring similar electrochemical energy stores and storing the data in digital memory devices.

A further preferred embodiment of the invention provides for the concurrence of a requested power P for a time interval Δt to be all the more likely given the greater the set difference is between the cell voltage after the requisite power output and the lowest permissible cell voltage.

The features of the various embodiments of the invention can also be advantageously combined with one another.

The following will reference preferred embodiments and the accompanying drawings in describing the invention in greater detail. Shown are:

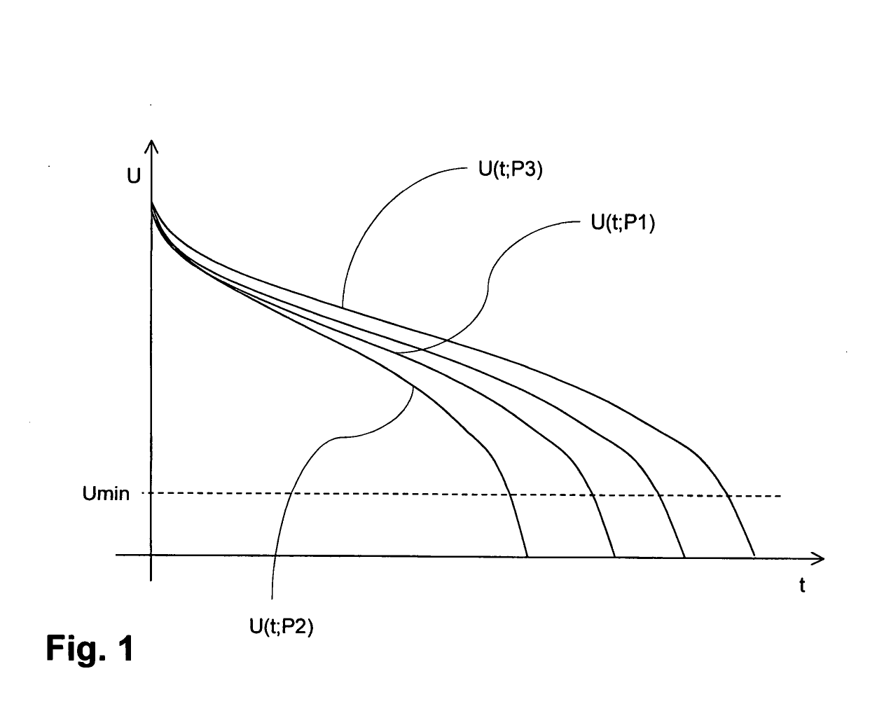

FIG. 1 a schematic view of a host of measurement curves, wherein each measurement curve corresponds to the chronological profile of the cell voltage during discharging of the electrochemical energy store at a specific power output;

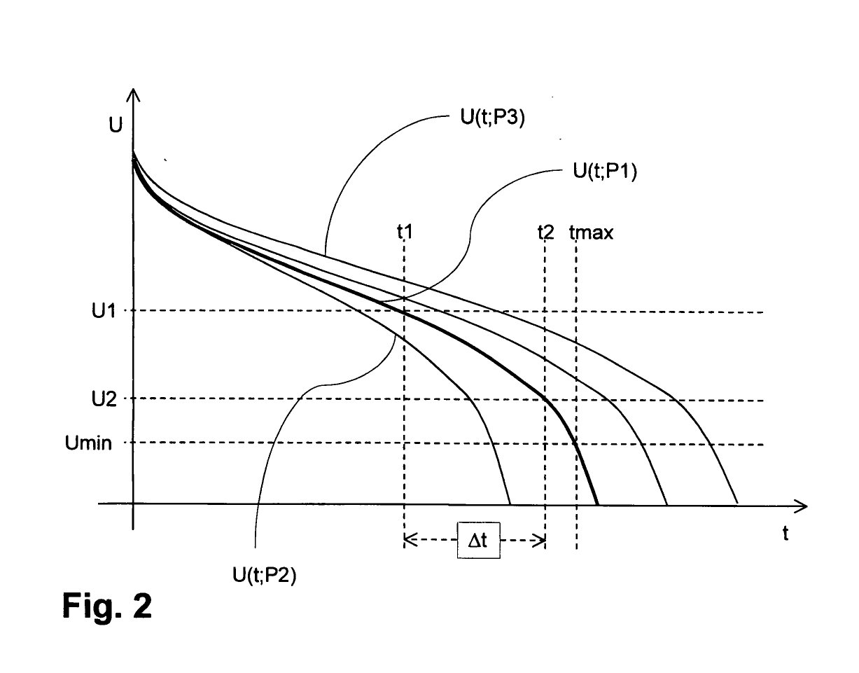

FIG. 2 a schematic view of the inventive method based on an embodiment at a first power output;

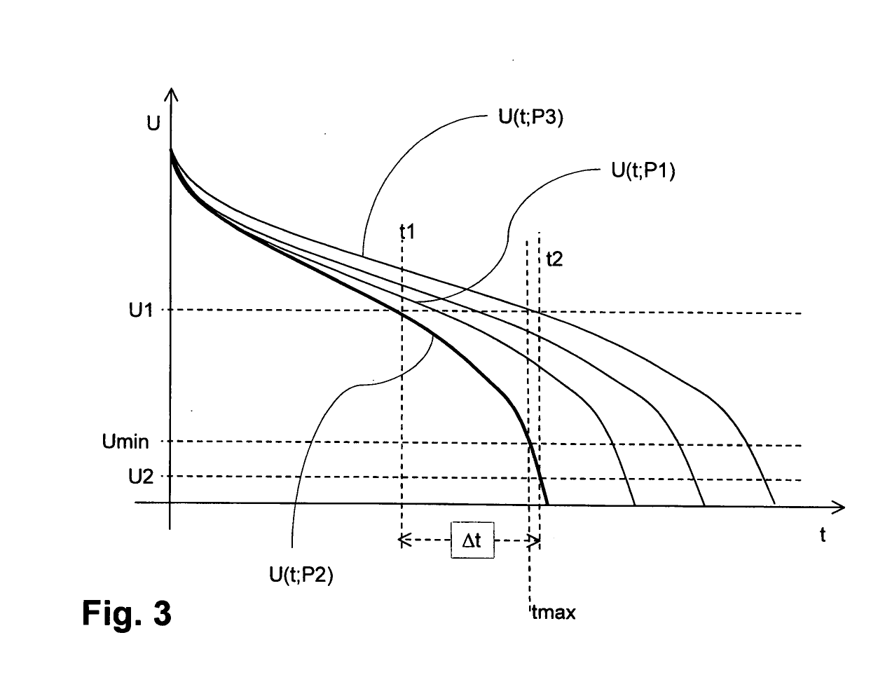

FIG. 3 a schematic view of the inventive method based on an embodiment at a second power output; and

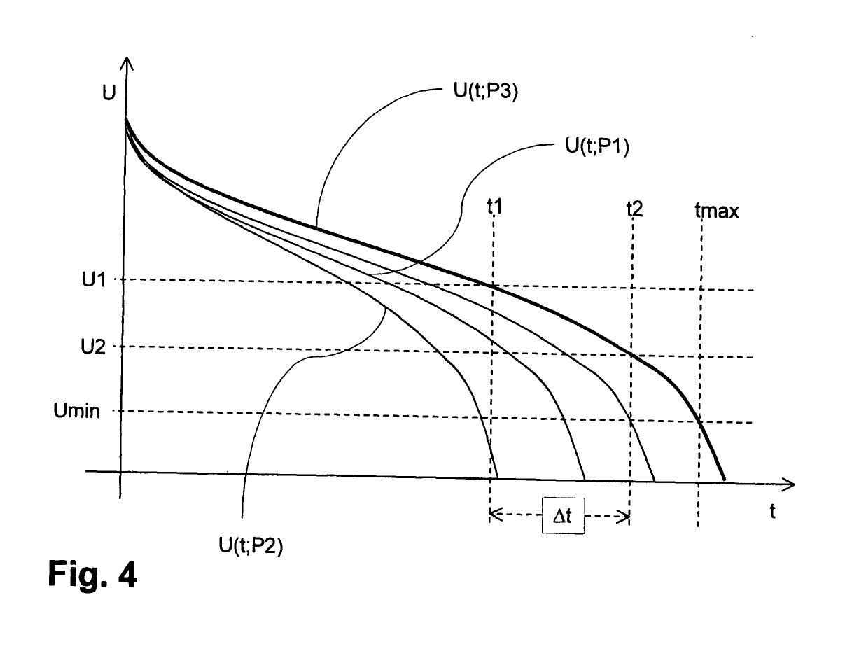

FIG. 4 a schematic view of the inventive method based on an embodiment at a third power output.

The measurement curves shown in FIG. 1 represent typical profiles of the cell voltage U measured as a function of time t for electrochemical energy stores at various power outputs P1, P2 or P3. All four measurement curves shown start at substantially the same cell voltage at the coordinate origin of time coordinates corresponding to the maximum charge of the electro-chemical energy store. The greater the constant output power P1, P2 or P3 during discharge, the steeper the drop generally is in the cell voltage U over time t. Hence, the curve associated with power P3 exhibits a flatter profile than all the other measurement curves which are obviously associated with higher performance values. The measurement curve associated with power P1 in particular exhibits a steeper drop than the measurement curve associated with power P3, yet progresses flatter than the measurement curve associated with power P1. It is hereby understood that voltage U is generally equal to the minimum tolerable cell voltage Umin that much earlier the steeper the corresponding measurement curve is.

Although the measurement curves shown in FIG. 1 progress continuously, the actual measurement curves obtained are preferably only stored for discrete time values so that in practice, instead of a continuum of voltage values for a continuum of time points, only one finite set of measurement values is available for predicting the power response. A continuum of measurement values is preferably made available from this finite number of measurement values by adjusting the applicable curve profiles by the associated voltage values U(t) being able to be calculated from the adjusted curve profiles at any given time point t which, however, have not actually been measured.

The embodiment of a power output prediction depicted in FIG. 2 starts from a predefined power P1, for example based on a query, its associated measurement curve U(t;P1) being highlighted in FIG. 2. The assumption is made in this embodiment that at the time the power is predicted, thus the prediction of the availability of the power to be output, the cells of which the power is to be predicted exhibit voltage U1. The measurement curve associated with power P1 assumes the voltage value U1 at time t1. It is further assumed that power P1 is required for a time interval Δt. It can be noted from the measurement curve shown in FIG. 2 that the cell voltage at time t2=t1+Δt will assume the value U2 given output of constant power P1. It can further be noted from FIG. 2 that the voltage value U2 is still clearly higher than the minimum cell voltage value Umin. Additionally, the time tmax, at which the measurement curve U(t;P1) assumes voltage value Umin, is somewhat offset from time t2 at which discharging ends.

By considering the measurement curve profile shown in FIG. 2, it can thus be said with some probability that an electrochemical cell, its electrochemical properties being represented by the profile of the measurement curve U(t;P1) in FIG. 2, and which exhibits voltage U1 at the start of the discharge operation in question, will assume the voltage value U2 after discharge at power P1, same being far enough distanced from the minimum cell voltage value Umin that it can be assumed with sufficient probability, reliability or certainty that the relevant electrochemical energy store will be capable of outputting the required power P1 over the required time interval Δt.

If a qualitative response to the query is thus needed as to whether the electrochemical energy store will be able to output the power P1 for the time interval Δt, the response to this query can thus be a qualitative “yes” or “with sufficient probability” or the like. In order to be able to give a quantitative response, for example in the form of a numerical probability, a series of measurements made on the respective electrochemical energy store or on similar electrochemical energy stores would be necessary, and with which the condition at issue is implemented several times in succession.

The age of the electrochemical energy store, or its temperature or previous history can preferably be hereby taken into account, for example the number of total discharges which have already occurred, i.e. falling short of the minimum cell voltage Umin. Model probability distributions which consider the probability of the validity of the prediction as a function of the difference between U2 and Umin and/or the difference between t2 and tmax can preferably also be taken as the basis. The free parameters of such model probability distributions are thereby preferably determined in a series of measurements.

The example shown in FIG. 3 refers to a case in which power P2 is required, in turn for time interval Δt. The current cell voltage U1 of the electrochemical energy store is associated with the measurement curve of power P2 at time t1 in FIG. 3. At time t2=t1+Δt, the cell voltage has dropped in a discharge operation at power P2 to voltage U2, which is clearly below the minimum cell voltage Umin. Discharging at said power P2 would therefore not be possible or only possible at the expense of damages or at least considerable aging of the respective cell. The prediction of the availability of power P2 for time interval Δt would therefore have to be negative or at least accompanied by a warning that such performance can only be assumed over this time interval at the expense of damage to the cell. A further possible response to a query would also be predicting the power P2 for the time tmax−t1, which, however, is less than the predefined time Δt.

FIG. 4 depicts another embodiment in which the time tmax, at which the cell voltage has dropped to value Umin with the discharge of power P3, is clearly offset from the time t2=t1+Δ1, wherein time t1 again corresponds to the time at which the measurement curve associated with power P3 assumes the voltage value U1 which corresponds to the current electrochemical energy store's cell voltage. In this situation, the queried power P3 for the queried time period Δt can be assured with high probability, certainty or reliability. The corresponding prediction is thus accordingly affirmative.

1. A method for predicting the electrical power that an electrochemical energy store can output comprising:
taking at least one measurement from a plurality of cell voltage measurements electronically processed as a function of time and taken and stored from the electrochemical energy store subject to a plurality of discharge operations at a constant power output over time,
wherein the plurality of measurements are collected in a form of a plurality of measurement curves, and each measurement curve corresponds to the cell voltage performance over time during the electrochemical energy store discharging at a specific power out put.

2. The method according to claim 1 in which at least one measurement from a plurality of cell voltage measurements is parameterized pursuant to operating temperatures of the electrochemical energy store and is electronically processed as a function of time.

3. The method according to claim 1, wherein a prediction is a response to IT-based querying of an electrical load or a control device of an electrical load related to the power to be output and a time interval over which the power to be output is output to the electrical load by the electrochemical energy store.

4. The method according to claim 3, wherein if the power to be output is not consistent with one of the performance values for which measurements were made, the prediction is obtained by interpolating between performance value measurements proximate the power to be output.

5. The method according to claim 3, wherein the response to a query as to whether the power can be output over the time interval is given as a probability.

6. The method according to claim 3, wherein the response to the query as to whether the power can be output over the time interval is given as a selection of a form response from a plurality of form responses, each form response representing a probability of a reliability or a certainty at which the power to be output over the time interval can be output.

7. The method according to claim 3, wherein making the prediction includes:
determining a first measuring point on a measuring curve for the power to be output, a corresponding cell voltage corresponding to a current cell voltage of the electrochemical energy store;
determining a cell voltage associated with the power to be output at a second measuring point on measuring curve, a corresponding time coordinate being offset from an initial time coordinate of the first measuring point by said time interval; and
determining the response as a function of the cell voltage associated with the power to be output.

8. The method according to claim 7, wherein the cell voltage associated with the power to be output is determined prior to generating the response and is corrected by a value which factors in a potential or actual change in an internal resistance of the electrochemical energy store as of the time it was placed into operation.

9. The method according to claim 7, wherein the concurrence of the requested power for the time interval increases in direct proportion to an estimated difference between a cell voltage after the requisite power output and a lowest permissible cell voltage.

10. A control device for an electrochemical energy store designed to implement the method of predicting the power able to be output by the electrochemical energy store in accordance with claim 1.

11. The method according to claim 8, wherein the potential or actual change in the internal resistance of the electromechanical energy store corresponds to an aging of the electromechanical energy store.
